(19) United States
(12) Patent Application Publication
(10) Pub. No.: US 2026/0190298 A1
(43) Pub. Date: Jul. 2, 2026

(54) OPEN TYPE 2 PHASE IMMERSION COOLING SYSTEM AND COOLING METHOD THEREOF

(71) Applicants: SK hynix Inc., Icheon-si (KR); Seoul National University R&DB Foundation, Seoul (KR)

(72) Inventors: NAMHYEON CHOI, Icheon-si (KR); SEUNGJIN RYU, Icheon-si (KR); JOONHEUM BAE, Icheon-si (KR); Min Soo KIM, Seoul (KR); Hoseong LEE, Seoul (KR); Jaegyun JANG, Seoul (KR); Joonhyung KIM, Seoul (KR)

(21) Appl. No.: 19/434,770

(22) Filed: Dec. 29, 2025

(30) Foreign Application Priority Data
Dec. 30, 2024 (KR) 10-2024-0200936

(51) Int. Cl. H05K 7/20

(52) U.S. Cl. CPC H05K 7/20809

(57) ABSTRACT

A two-phase liquid immersion cooling system and a method of operating the same are disclosed. The disclosed system for two-phase liquid immersion cooling of a heat generating device includes a two-phase liquid immersion coolant in which the heat generating device is immersed; a single-phase liquid-immersion coolant that is immiscible with the two-phase liquid-immersion coolant, is less dense than the two-phase liquid-immersion coolant, and is located above the two-phase liquid-immersion coolant; a cooling tank containing the heat generating device, the two-phase liquid immersion coolant, and the single-phase liquid coolant; and a heat exchanger configured to remove heat from the single-phase liquid immersion coolant, wherein the two-phase liquid immersion cooling system is configured so that when the two-phase liquid immersion coolant is vaporized by the heat generating device, the vaporized two-phase liquid immersion coolant is condensed by the single-phase liquid immersion coolant.

### CROSS-REFERENCES TO RELATED APPLICATION

The present application claims, under 35 U.S.C. § 119(a), the benefit of Korean Patent Application No. 10-2024-0200936, filed on Dec. 30, 2024 which is hereby incorporated by reference in its entirety.

### BACKGROUND

### 1. Field

The present disclosure relates to a system for cooling a heat generating device and a method of operation thereof, and more particularly to an open type two phase liquid immersion cooling system and a method of operation thereof.

### 2. Description of the Related Art

Today, as the impact of the climate crisis continues to expand globally, countries are taking various measures to reduce greenhouse gases. As interest in reducing greenhouse gas emissions grows, data centers, which are recognized as infrastructure which is expected to grow in the future, are also considering measures to reduce their massive power usage. The power usage of data centers is mainly divided into IT equipment that store and process data and the air conditioning and infrastructure to maintain these computing devices. Since the number and efficiency of IT equipment is not expected to be significantly reduced, efforts for data center energy reduction are better focused on how efficiently the air conditioning system, which accounts for the largest share of non-server power usage, is configured.

As power demand management and environmental sanctions on data centers are tightening, especially in major European countries, global data center companies are actively looking to improve cooling solutions for sustainable operations. Therefore, immersion cooling, which cools IT equipment by immersing it in a refrigerant, is being actively considered. Immersion cooling uses relatively little energy to cool high-density servers by immersing the IT equipment in a non-conductive liquid.

Liquid immersion cooling uses liquid to remove heat from the heat generating devices, and the cooling of the liquid is performed through a separate heat rejection system (Heat Rejection System, Dry Cooler, etc.), so liquid immersion cooling does not require equipment with high power requirements such as compressors and fans, and can use a heat exchanger to circulate and remove heat from the heated liquid.

In general, there are two types of immersion cooling systems: single-phase immersion cooling systems and two-phase immersion cooling systems. A single-phase immersion cooling system removes heat from a heat generating device (such as a server) by circulating a dielectric fluid against the device. Heat is removed from the device (server, etc.) is by convective heat transfer, which is more efficient when there is good circulation within the tank, so flow is an important factor. In single-phase immersion cooling systems, the dielectric solution is less likely to volatilize, has high chemical stability, and may be used in contact with the atmosphere, but it has the disadvantage of low cooling effect and requires a separate device for circulation.

The two-phase liquid immersion cooling system is a system in which the dielectric solution is vaporized by the server heat, and the vaporized solution is condensed in the upper heat exchanger, liquefied, circulated, and cooled. The primary cooling mechanism is vaporization, whereby energy is absorbed by the dielectric solution in a state change from liquid to gas, and the vaporized solution is condensed back into a liquid. Since the refrigerant in the gaseous state is circulated by supplying cold water to the condensing part installed inside the tank, no additional facilities are required, but sealing management is required. In addition, if air other than refrigerant is introduced into the tank, the cooling performance may decrease due to hydrolysis of the refrigerant due to air contact, so it is important to pay attention to the sealing design.

Meanwhile, there is an urgent need to develop a two-phase liquid-immersion cooling system and method that may address the disadvantages of two-phase liquid-immersion cooling systems and increase the cooling performance without requiring an expensive and complex sealing system.

### SUMMARY

Embodiments of the present disclosure are directed to an open two-phase liquid-immersion cooling system in which condensation of a two-phase liquid-immersion coolant is performed within a single-phase liquid-immersion coolant in the upper phase, thereby increasing the cooling performance of a heat generating device while being easy to install and implement because it does not include a separate condenser.

Furthermore, another technical challenge that the present disclosure seeks to fulfill is to provide a two-phase liquid immersion cooling method having the aforementioned advantages.

According to one embodiment of the present disclosure, a system for two-phase liquid immersion cooling of a heat generating device, comprising: a two-phase liquid immersion coolant in which the heat generating device is immersed; a single-phase liquid immersion coolant that is immiscible with the two-phase liquid immersion coolant, is less dense than the two-phase liquid immersion coolant, and is located above the two-phase liquid immersion coolant; a cooling tank containing the heat generating device, the two-phase liquid immersion coolant, and the single-phase liquid coolant; and a heat exchanger configured to remove heat from the single-phase liquid immersion coolant, wherein the two-phase liquid immersion cooling system is configured so that when the two-phase liquid immersion coolant may be vaporized by the heat generating device, and the vaporized two-phase liquid immersion coolant may be condensed by the single-phase liquid immersion coolant.

In this case, the heat exchanger cools the single-phase liquid immersion coolant so that a temperature of the single-phase liquid immersion coolant is maintained below the boiling point of the two-phase liquid immersion coolant.

Further, the single-phase liquid-immersion coolant may be located on the heat generating device immersed in the two-phase liquid-immersion coolant.

Further, the cooling tank may not be hermetically sealed.

Further, an upper portion of the single-phase liquid immersion coolant of the cooling tank may be at least partially open to atmosphere.

Further, the two-phase liquid-immersion cooling system may further comprise an outflow portion configured to transport the single-phase liquid-immersion coolant to the heat exchanger; and an inflow portion configured to receive cooled single-phase liquid-immersion coolant from the heat exchanger into the cooling tank.

Further, the single-phase liquid immersion coolant may prevent the two-phase liquid immersion coolant from contacting air, and the vaporized two-phase liquid immersion coolant may be cooled below its boiling point by the single-phase liquid immersion coolant.

Further, the two-phase liquid-immersion cooling system may further comprise a container that encloses the heat generating device, prevents direct contact of the heat generating device with the two-phase liquid immersion coolant, and is immersed in the two-phase liquid immersion coolant.

Further, a method of two-phase liquid immersion cooling a heating device according to one embodiment of the present disclosure comprises the steps of positioning the heat generating device inside a cooling tank, and immersing the heat generating device within a two-phase liquid immersion coolant; positioning a single-phase liquid coolant above the two-phase liquid coolant, which is immiscible with the two-phase liquid coolant and has a density lower than the two-phase liquid coolant; and the step of removing heat from the single-phase liquid immersion coolant by a heat exchanger, wherein the two-phase liquid immersion coolant is vaporized by the heat generating device, and the vaporized two-phase liquid immersion coolant may be condensed by the single-phase liquid immersion coolant.

In this case, the single-phase liquid immersion coolant may be positioned above the heat generating device which is immersed in the two-phase liquid immersion coolant.

Further, the cooling tank may not be hermetically sealed.

Further, an upper portion of the single-phase liquid immersion coolant in the cooling tank may be at least partially open to atmosphere.

The method may further comprise the steps of flowing the single-phase liquid-immersed coolant into the heat exchanger, and flowing single-phase liquid-immersion coolant from the heat exchanger into the cooling tank.

Further, the single-phase liquid coolant may prevent the two-phase liquid immersion coolant from contacting air, and the vaporized two-phase liquid immersion coolant may be cooled below its boiling point by the single-phase liquid immersion coolant.

According to embodiments of the present disclosure, condensation of the two-phase liquid immersion coolant may be performed in the single-phase liquid immersion coolant at the top, thereby providing a two-phase liquid immersion cooling system that does not include a separate condenser, which may increase the cooling performance of the heating device while being easy to install and implement.

Furthermore, according to embodiments of the present disclosure, condensation of the two-phase liquid-immersion coolant may be performed on the single-phase liquid-immersion coolant on top, thereby providing a two-phase liquid-immersion cooling method that does not include a separate condenser, which may increase the cooling performance of the heating device while being easy to install and implement.

### BRIEF DESCRIPTION OF THE DRAWINGS

FIG. 1 illustrates an example of a two-phase liquid-immersion cooling system.

FIG. 2 illustrates an example of a two-phase liquid immersion cooling system in which a plurality of heating devices is housed within the two-phase liquid immersion cooling system.

FIG. 3 illustrates another example of a two-phase liquid-immersion cooling system.

FIG. 4 illustrates the structure of a two-phase liquid-immersion cooling system.

FIG. 5 illustrates one embodiment of an open two-phase liquid-immersion cooling system according to the present disclosure.

FIG. 6 illustrates an embodiment of exchanging heat generating elements in a two-phase liquid-immersion cooling system according to the present disclosure.

FIG. 7 illustrates the structure of an open two-phase liquid-immersion cooling system according to one embodiment of the present disclosure.

FIG. 8 is a flow diagram illustrating a process of performing two-phase liquid immersion cooling in an open two-phase liquid immersion cooling system according to one embodiment of the present disclosure.

### DETAILED DESCRIPTION

Hereinafter, embodiments of the present disclosure will be described in detail with reference to the accompanying drawings.

The embodiments of the disclosure to be described below are provided for the purpose of explaining the disclosure more clearly to those having ordinary knowledge in the art, and the scope of the disclosure is not limited by the following embodiments, and the following embodiments may be modified in various other forms.

The terms used in this specification are intended to describe particular embodiments and are not intended to limit the disclosure. Terms used herein in the singular form may include the plural form, unless the context clearly indicates otherwise. Further, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Further, as used herein, the term “connected” is intended to mean not only that certain elements are directly connected, but also that they are indirectly connected by the interposition of other elements between them.

Further, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like as used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Embodiments of the present disclosure will now be described in detail with reference to the accompanying drawings. The sizes or thicknesses of the areas or parts shown in the accompanying drawings may be somewhat exaggerated for clarity and ease of description. Throughout the detailed description, like reference numerals designate like components.

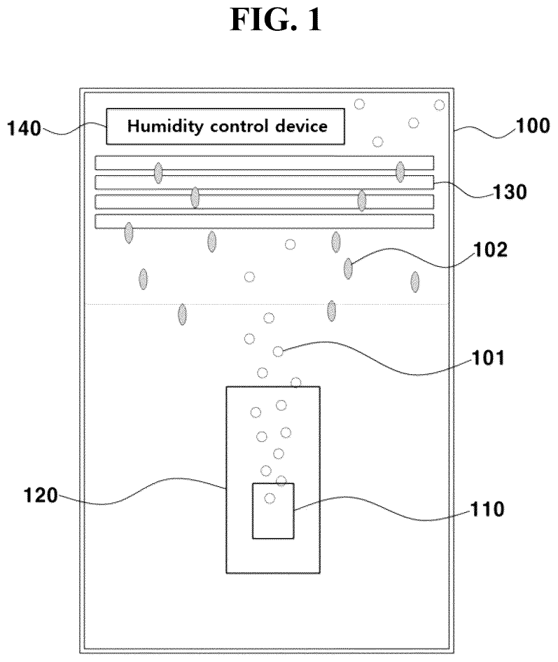

FIG. 1 illustrates an example of a two-phase liquid immersion cooling system. Referring to FIG. 1, a two-phase liquid immersion cooling system 100 comprises a cooling tank for storing a heat generating device 110, a two-phase immersion coolant 101 that is stored in the cooling tank and immerses the heat generating device 110, a condenser 130 for condensing the vaporized two-phase immersion coolant 101, and a humidity control device 140 for controlling the humidity in the sealed storage tank.

The two-phase liquid coolant 101 may be composed of a non-conductive, high heat transfer rate, low boiling point material, such as a dielectric liquid.

The heat generating device 110 is enclosed in a container 120 to prevent contact with the two-phase liquid coolant 101 and is immersed in the two-phase liquid coolant 101. The heat generating device 110 may be an electronic device such as one or more computer server, server rack, central processing unit (CPU), graphics processing unit (GPU), storage device such as a hard drive, network device, or combination of electronic devices, for example.

When the heat generating device 110 is heated, the two-phase liquid coolant 101 is heated above its boiling point by the heat generated by the heat generating device 110 and vaporized, and the vaporized two-phase liquid coolant is condensed at the upper condenser 130 and liquefied into liquid coolant 102, which is circulated and cooled.

The two-phase liquid coolant 101 cools the heat generating device 110 by utilizing the latent heat of changing from a liquid phase to a vapor phase. As heat is generated in the heat generating device, some of the two-phase liquid coolant 101 around the heat generating device vaporizes and turns into bubbles, which are then evaporated at the upper surface of the coolant. The evaporated vapor phase two-phase liquid coolant 101 is condensed by the condenser 130 at an upper part of the storage tank and then changed to liquid phase and moved to the lower part of the storage tank.

On the other hand, if the vaporized two-phase liquid coolant condenses and is blown into the atmosphere without being circulated, there may be losses in the amount used to cool the heat generating device as the amount circulated continues to decrease. To prevent such losses, the two-phase liquid-immersion cooling system 100 should be hermetically sealed.

If the two-phase liquid cooling system 100 is made in a hermetic form, the power and communication connections of the two-phase liquid cooling system 100 itself and the heat generating device housed therein may utilize separate connectors to avoid breaking the hermetic seal of the two-phase liquid cooling system, which may have the disadvantage of making the system internally complex and difficult to implement.

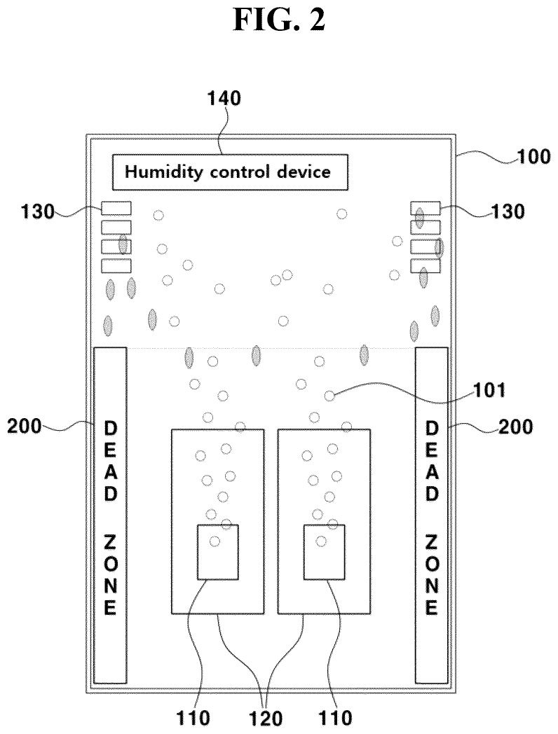

FIG. 2 illustrates an example in which a plurality of heat generating devices is stored within a two-phase liquid-immersion cooling system. Referring to FIG. 2, increasing the amount of storage within the two-phase liquid cooling system 100 to cool the plurality of heat generating devices 110 requires an increase in the size of condenser 130 or humidity control device 140 which increases the volume occupied within the two-phase liquid cooling system 100.

Thus, the internal structure of the two-phase liquid-immersion cooling system 100 is complicated, and some areas 200 have the disadvantage of becoming dead zones, which are areas where it is undesirable to locate the heat generating device 110, due to the large amount of two-phase liquid coolant condensed by the condenser 130 or the like. In the example of FIG. 2, the dead zones 200 are located directly under condensers 130 at sides of the storage tank.

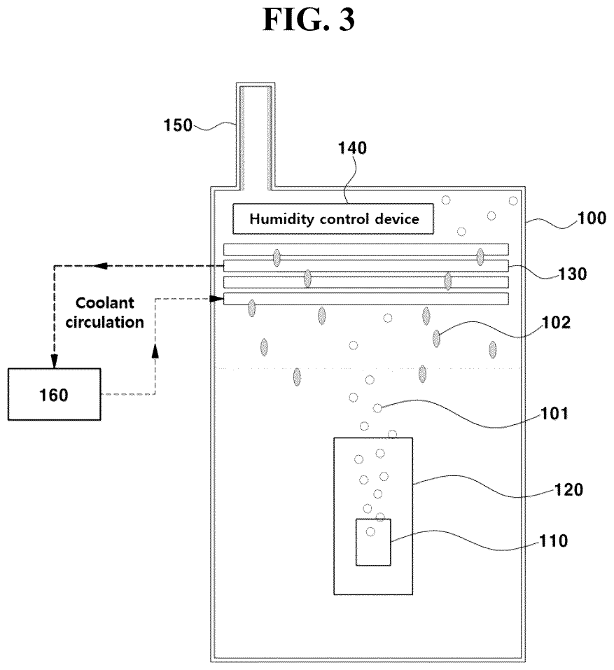

FIG. 3 is a drawing illustrating another example of a two-phase liquid-immersion cooling system.

Referring to FIG. 3, for an environment in which the gaseous two-phase liquid coolant is condensed and circulated, the two-phase liquid coolant system 100 may be hermetically sealed and may further include a vapor pressure regulator 150 inside the two-phase liquid coolant system 100 as the vapor pressure inside the two-phase liquid coolant system 100 rises when the heat from the heat generating device 110 is greater than the capacity of the condenser 130.

In addition, the two-phase liquid-immersion cooling system 100 according to another example may further include a moisture control device 160 that regulates the moisture in the system to prevent atmospheric moisture from entering the gaps in the system and hydrolyzing the two-phase liquid coolant in order to increase the performance of the condenser 130. The moisture control device 160 may be a coolant circulation system including an external cooler and a pump that pumps chilled coolant through the condenser 130, for example.

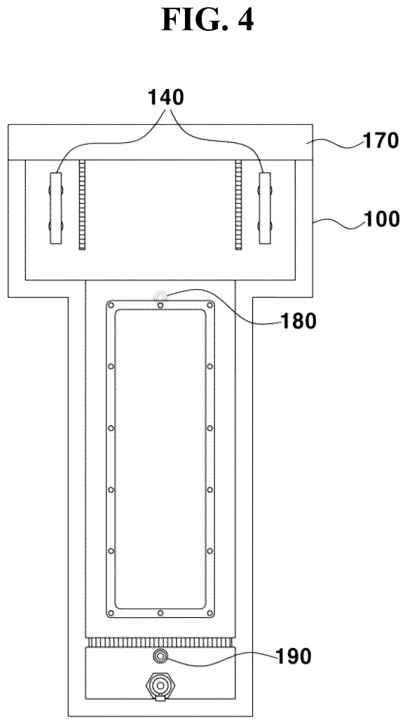

FIG. 4 is a drawing illustrating the structure of a two-phase liquid-immersion cooling system 100.

Referring now to FIG. 4, the two-phase liquid-immersion cooling system 100 according to another example may comprise a lid portion 170 for sealing the system to prevent loss of the two-phase liquid-immersion coolant, as described above, and may comprise an inlet portion 190 and an outlet portion 180 for flowing the two-phase liquid-immersion coolant 101 into and out of the cooling tank.

As described above, it is desirable to reduce the cost and complexity of components used to prevent loss of the two-phase liquid coolant, and to this end, embodiments of a two-phase liquid coolant system for reducing the system complexity, ease of use and manufacturing, and increasing the condensing efficiency of the two-phase liquid coolant are described below.

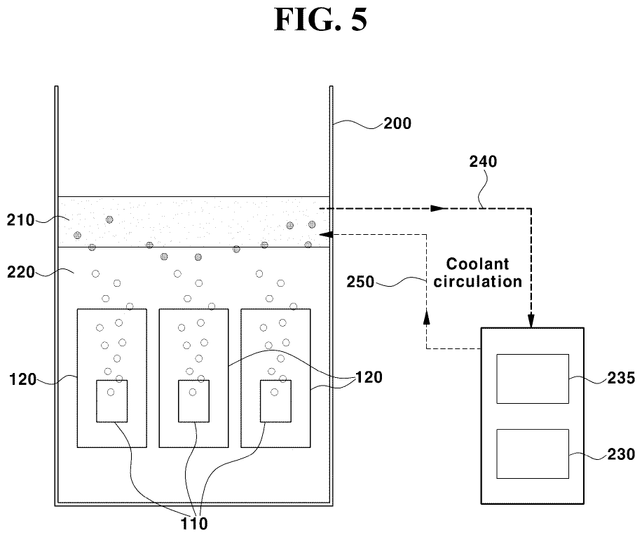

FIG. 5 is a diagram illustrating one embodiment of an open two-phase liquid-immersion cooling system according to the present disclosure.

Referring to FIG. 5, an open two-phase liquid immersion cooling system 200 according to the disclosure may comprise a cooling tank 205 housing a plurality of heat generating devices 110, a two-phase liquid coolant 220 in which the heat generating devices 110 are immersed, a single-phase liquid coolant 210 that is not mixed with the two-phase liquid coolant 220, is less dense than the two-phase liquid coolant 220, and is disposed on top of the two-phase liquid coolant 220, a heat exchanger 235, and a pump 230 for removing heat from the single-phase liquid coolant 210. The heat exchanger 235 may be a passive device, but embodiments are not limited to that configuration.

The single-phase liquid coolant 210 may comprise a substance that is characterized in that it does not mix with, chemically react with, or hydrolyze upon contact with the two-phase liquid coolant 220, and the temperature maintained by the heat exchanger 235 is below the boiling point of the two-phase liquid coolant. For example, the single-phase liquid coolant 210 may be an oil-based substance, such as a mineral oil-based, vegetable-based, synthetic ester-based, or a combination thereof, and one or more of several substances, such as a fluorocarbon, ether, hydrocarbon, silicone oil, a glycol solution, and the like, may be optionally used or combined to meet the above conditions.

The two-phase liquid-immersion cooling system 200 may include an outflow portion 240 for outflowing the single-phase liquid-immersion coolant 210 to the heat exchanger 235 for heat exchange, and an inflow portion 250 for inflowing cooled single-phase liquid-immersion coolant from the heat exchanger 235 into the cooling tank 205. The two-phase liquid-immersion coolant 220 is vaporized by heat generated by the heat generating device 110, and the vaporized two-phase liquid-immersion coolant 220 is condensed by the single-phase liquid-immersion coolant 210.

Two-phase liquid coolants cool heat generating devices by utilizing the latent heat from the transition from the liquid phase to the vapor phase. When heat is generated by a heat generating device, some of the two-phase liquid coolant around the heat generating device vaporizes into bubbles and rises to the top of the liquid phase portion of the two-phase coolant where it evaporates. The evaporated vapor phase two-phase liquid coolant is condensed by the single-phase liquid coolant cooled below the boiling point of the upper two-phase liquid coolant and is then transformed into a liquid phase and moved to the lower part of the reservoir. An embodiment of a two-phase cooling system may include a lower liquid column of two-phase liquid coolant which is completely covered by an upper column of single-phase liquid coolant.

The two-phase liquid coolant may comprise a substance that has a boiling point lower than the temperature of the cooled single-phase liquid coolant, has a lower density than the single-phase liquid coolant, is immiscible with the single-phase liquid coolant, and does not chemically react with it. In some embodiments, the two-phase liquid-immersion coolant may be a non-conductive, hydrofluorocarbon-based refrigerant, with a boiling point of 45 to 70 degrees Celsius, which is somewhat lower than the boiling point of water, which is 100 degrees Celsius, allowing for phase change heat transfer at relatively low temperatures.

The temperature of the single-phase liquid coolant 210 may be maintained below the boiling point of the two-phase liquid coolant 220 by the heat exchanger 235. The condensed two-phase liquid coolant has a higher density than the single-phase liquid coolant, and thus descends to the bottom of the single-phase liquid coolant. The immiscibility of the single-phase liquid coolant 210 and two-phase liquid coolant 220 provides separation between the fluid columns, and the density variation between the liquids helps maintain separation, ensures that the single-phase liquid remains above the two-phase liquid, and allows the condensed two-phase liquid to return to the lower column of two-phase liquid.

Depending on the embodiment, the amount of the two-phase liquid immersion coolant 220 may be sufficient to immerse and cool the heat generating device 110. Further, the single-phase liquid coolant 210 may sufficiently cover the two-phase liquid coolant 220 to protect the single-phase liquid coolant from air contact, and may have a depth sufficient to condense all of the evaporated two-phase liquid coolant 220. Depending on the embodiment, the volume ratio of the two-phase liquid immersion coolant 220 to the single-phase liquid immersion coolant 210 may be set within a range of 60:40 to 90:10. The depth of the single-phase liquid coolant 210 may vary depending on the materials, equipment and temperatures of the specific embodiment, and may be at least 5 centimeters, at least 10 centimeters, at least 20 centimeters, at least 30 centimeters, at least 50 centimeters, or at least one meter, for example.

Depending on the embodiment, the heat generating device 110 may be enclosed in a cooling tank 205 that prevents direct contact of the heat generating device 110 with the two-phase liquid coolant 220 and is wetted by the two-phase liquid coolant.

The single-phase liquid coolant 210 may be located above the heat generating device 110, which is immersed in the two-phase liquid coolant 220.

According to the embodiment of FIG. 5, the two-phase liquid coolant 220 vaporized by the heat generated by the heat generating device 110 is not condensed by a separate condenser, but is condensed by cooling the two-phase liquid coolant vaporized by the heat generating device 110 to below the boiling point as a single-phase liquid coolant 210, so that the air contact of the two-phase liquid coolant is blocked and no losses due to hydrolysis by air contact occur.

Furthermore, embodiments of the present disclosure have the effect of preventing the vaporized two-phase liquid coolant from diffusing into the air, thereby preventing harm that may occur when a user inhales the vaporized two-phase liquid coolant.

Furthermore, by implementing a two-phase liquid-immersion cooling system as shown in FIG. 5, the structure is simplified and the space inside the system is easily secured compared to a conventional configuration that includes a condenser, a humidity control device, a vapor pressure control device, and the like inside the cooling tank, as described above, so that the system is easy to construct and has the effect of reducing costs and improving cooling efficiency.

In embodiments of the present disclosure the single-phase liquid coolant does not mix with the two-phase liquid coolant, but is separated to the top of the two-phase liquid coolant due to its lower density, and acts as a condenser, vapor pressure regulator, and humidity controller, reducing system complexity and facilitating implementation by eliminating the need to add multiple configurations to prevent loss of the single-phase liquid coolant.

Furthermore, since the single-phase liquid coolant shields the two-phase liquid coolant, the two-phase liquid coolant does not come into contact with air and therefore does not suffer losses due to air contact, the cooling tank need not be hermetically sealed, i.e., the upper portion of the single-phase liquid coolant 210 of the cooling tank may be at least partially open to atmosphere.

In addition, unlike systems in which condensation of the vaporized two-phase liquid coolant is possible only on the surface of the condenser, condensation of the vaporized two-phase liquid coolant occurs throughout the entire area of the single-phase liquid coolant, and the loss of the two-phase liquid coolant to the atmosphere may be effectively controlled, which has the effect of increasing the condensation efficiency.

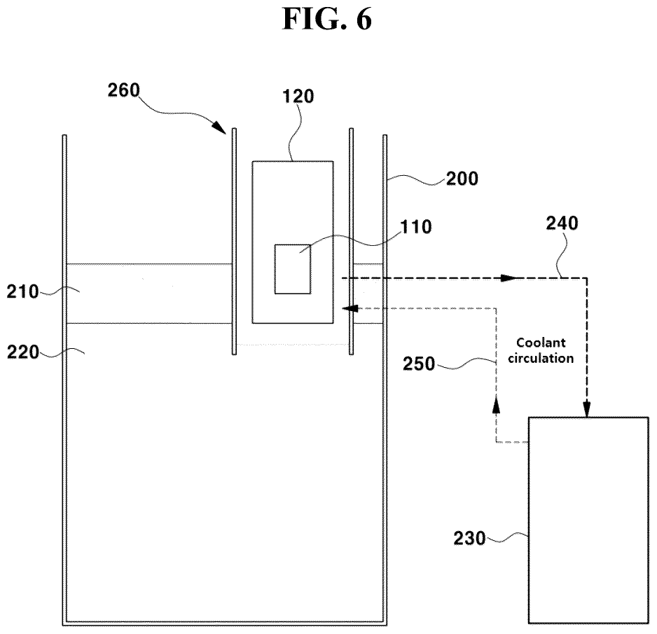

FIG. 6 is a diagram illustrating an embodiment of exchanging a heat generating device in a two-phase liquid-immersion cooling system according to the present disclosure.

Referring to FIG. 6, a two-phase liquid-immersion cooling system 200 according to the present disclosure may comprise a heat generating device 110, such that when servicing a server or other system, the heat generating device 110 may be inserted into the single-phase liquid coolant area with a tool, such as a jig, and then the heat generating device may be removed, at which time a portion of the single-phase liquid coolant 210 may be returned to the outlet 240 using a pump 230, and once the replacement is complete, the single-phase liquid coolant 210 may be reintroduced to the inlet 250 using the pump 230.

Accordingly, the present disclosure has the effect of reducing the amount of coolant loss compared to a conventional enclosed two-phase liquid-immersion cooling system, and the two-phase liquid-immersion cooling system may be configured as an open type, and there is no separate configuration of a condenser, a vapor pressure regulating device, a moisture regulating device, and the like, so that management such as maintenance of the heat generating device may be conveniently performed.

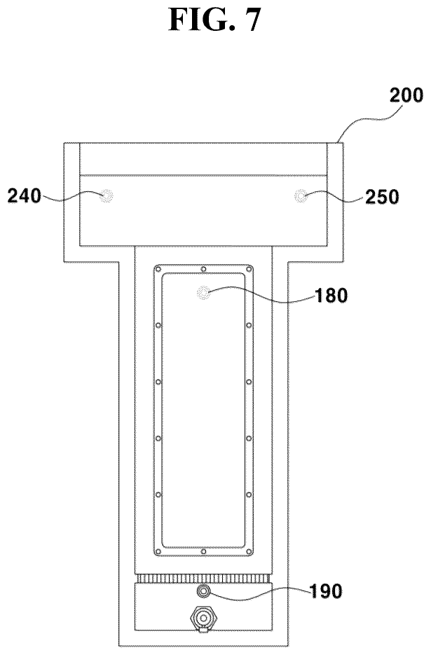

FIG. 7 is a drawing illustrating a structure of an open two-phase liquid-immersion cooling system according to one embodiment of the present disclosure.

Referring to FIG. 7, the two-phase liquid-immersion cooling system 200 according to the present disclosure may be configured as open, e.g., not including a cover or lid portion 170 to prevent loss of the single-phase liquid-immersion coolant as described above, and may comprise an inlet portion 250 and an outlet portion 240 for flowing single-phase liquid-immersion coolant 210 into and out of the heat exchanger 235.

In the two-phase liquid-immersion cooling system 200 of FIG. 7, as described above, the single-phase liquid-immersion coolant 210 may block air contact of the two-phase liquid-immersion coolant 220 so that no loss of hydrogen due to air contact may occur. Furthermore, as described above, compared to a conventional configuration that includes a condenser, a humidity control device, a vapor pressure control device, and the like inside the cooling tank, the structure is simplified and the space inside the system is easily secured, thereby facilitating system implementation, reducing costs, and improving cooling efficiency.

In an embodiment, the single-phase liquid coolant does not mix with the two-phase liquid coolant, but is separated to the top of the two-phase liquid coolant due to its lower density, and acts as a condenser, vapor pressure regulator, and humidity controller, reducing system complexity and facilitating implementation by eliminating the need to add multiple configurations to prevent loss of the single-phase liquid coolant.

In the liquid-immersion cooling system according to one embodiment of the present disclosure, the single-phase liquid coolant shields the two-phase liquid coolant, so that the two-phase liquid coolant does not come into contact with air and therefore does not suffer losses due to air contact, and the cooling bath need not be hermetically sealed, i.e., the upper portion of the single-phase liquid coolant (210) of the cooling bath may be at least partially open. Furthermore, unlike a system in which condensation of the vaporized two-phase liquid coolant is possible only on the surface of the condenser, condensation of the vaporized two-phase liquid coolant occurs throughout the entire area of the single-phase liquid coolant, and the loss of the two-phase liquid coolant to the atmosphere may be effectively controlled, which has the effect of increasing the condensation efficiency.

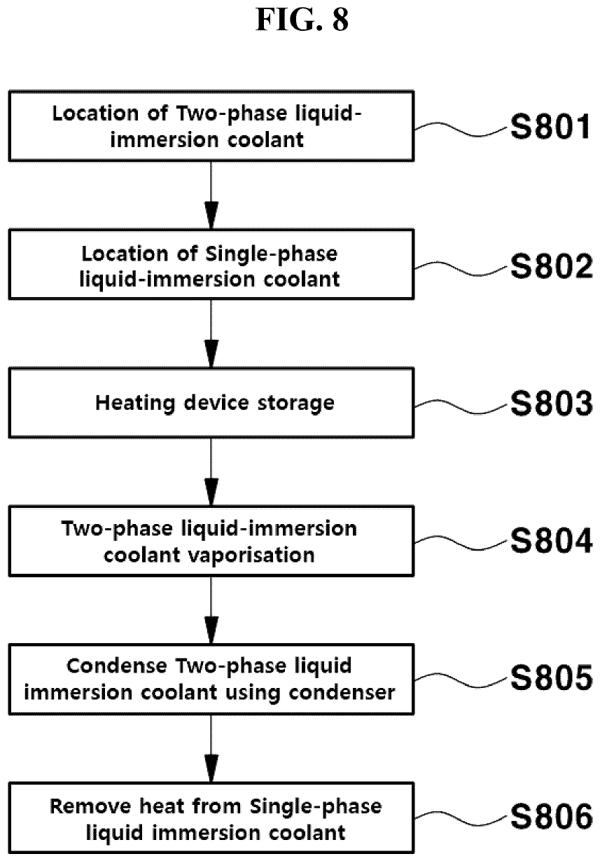

FIG. 8 is a flow diagram illustrating the process of performing two-phase liquid immersion cooling in an open two-phase liquid immersion cooling system according to one embodiment of the present disclosure.

Referring to FIG. 8, an open two-phase liquid-immersion cooling system according to one embodiment of the present disclosure places a two-phase liquid-immersion coolant in a cooling tank in step S801. Next, in step S802, a single-phase liquid coolant is placed on top of the two-phase liquid coolant, which is not mixed with the two-phase liquid coolant and has a lower density than the two-phase liquid coolant. Next, in step S803, the heat generating device is placed inside a cooling bath for cooling the heat generating device, and is immersed in the two-phase liquid immersion coolant.

Depending on the embodiment, the heat generating device may be stowed after the single-phase liquid coolant and the two-phase liquid coolant have been placed in the cooling bath, or the heat generating device may be placed in the cooling bath first, immersed in the two-phase liquid coolant, and then the single-phase liquid coolant is placed on top of the heat generating device. The order in which the heat generating device is stowed is not limited, and once the heat generating device is stowed, the single-phase liquid coolant is positioned on the heat generating device that has been immersed in the two-phase liquid coolant.

In step S804, heat is generated by the heat generating device, and this heat vaporizes the two-phase liquid coolant.

In step S805, the vaporized two-phase liquid coolant is condensed by the single-phase liquid coolant, i.e., the single-phase liquid coolant blocks contact of the two-phase liquid coolant with air, and the heat generating device cools the vaporized two-phase liquid coolant below boiling point to condense it.

In step S806, the single-phase liquid immersion coolant is discharged to the heat exchanger, heat is removed from the single-phase liquid immersion coolant by the heat exchanger, and the cooled single-phase liquid immersion coolant from the heat exchanger is introduced back into the cooling tank to be used again as a coolant.

The cooling tank of the two-phase liquid-immersion cooling system of FIG. 8 may be open and unsealed, and an upper portion of the cooling basin of the single-phase liquid-immersion coolant may be at least partially open.

Therefore, according to the method of FIG. 8, the air contact of the two-phase liquid coolant is blocked as described above, so that losses due to hydrolysis by air contact do not occur, and compared to the conventional configuration that includes a condenser, a humidity control device, a vapor pressure control device, and the like inside the cooling tank, the structure is simplified and the space inside the system is easily secured, so that the system is easy to implement, and the cost is reduced and the cooling efficiency is improved.

In an embodiment of the method of FIG. 8, the single-phase liquid coolant does not mix with the two-phase liquid coolant, but is separated to the top of the two-phase liquid coolant due to its lower density, and acts as a condenser, vapor pressure regulator, and humidity controller, eliminating the need for multiple configurations to be added to prevent loss of the single-phase liquid coolant, reducing system complexity and making it easier to implement.

Furthermore, since the single-phase liquid coolant shields the two-phase liquid coolant, the two-phase liquid coolant does not come into contact with air, so that there is no loss due to air contact, and the cooling tank does not need to be hermetically sealed. In addition, unlike a system in which condensation of the vaporized two-phase liquid coolant is possible only on the surface of the condenser, condensation of the vaporized two-phase liquid coolant occurs throughout the entire area of the single-phase liquid coolant, and the loss of the two-phase liquid coolant to the atmosphere may be effectively controlled, which has the effect of increasing the condensation efficiency.

This description discloses preferred embodiments of the present disclosure, and although certain terms are used, they are used in a general sense only to facilitate the description and understanding of the disclosure and are not intended to limit the scope of the disclosure. In addition to the embodiments disclosed herein, other modifications based on the technical ideas of the present disclosure are possible, as will be apparent to those of ordinary skill in the art to which the present disclosure belongs. One having ordinary knowledge in the art will recognize that the open two-phase liquid-immersion cooling system according to the embodiments described with reference to FIGS. 1 to 8 and the method of operation thereof may be variously substituted, altered and modified without departing from the technical idea of the disclosure. The scope of the disclosure is therefore not to be defined by the embodiments described, but by the technical idea recited in the patent claims.

What is claimed is:

1. A system for two-phase liquid immersion cooling of a heat generating device, the system comprising:
a two-phase liquid immersion coolant in which the heat generating device is immersed;
a single-phase liquid-immersion coolant that is immiscible with the two-phase liquid-immersion coolant, is less dense than the two-phase liquid-immersion coolant, and is located above the two-phase liquid-immersion coolant;
a cooling tank containing the heat generating device, the two-phase liquid immersion coolant, and the single-phase liquid coolant; and
a heat exchanger configured to remove heat from the single-phase liquid immersion coolant,
wherein the two-phase liquid immersion cooling system is configured so that when the two-phase liquid immersion coolant is vaporized by the heat generating device, the vaporized two-phase liquid immersion coolant is condensed by the single-phase liquid immersion coolant.

2. The system of claim 1, wherein the heat exchanger is configured to cool the single-phase liquid-immersion coolant so that a temperature of the single-phase liquid-immersion coolant is maintained below the boiling point of the two-phase liquid-immersion coolant.

3. The system of claim 1, wherein the single-phase liquid immersion coolant is located above the heat generating device immersed in the two-phase liquid immersion coolant.

4. The system of claim 1, wherein the cooling tank is not hermetically sealed.

5. The system of claim 1, wherein an upper portion of the single-phase liquid immersion coolant of the cooling tank is at least partially open to atmosphere.

6. The system of claim 1, further comprising:
an outflow portion configured to transport the single-phase liquid immersion coolant to the heat exchanger; and
an inflow portion configured to receive cooled single-phase liquid immersion coolant from the heat exchanger into the cooling tank.

7. The system of claim 1, wherein the single-phase liquid immersion coolant prevents the two-phase liquid immersion coolant from contacting air, and the vaporized two-phase liquid immersion coolant is cooled below its boiling point by the single-phase liquid immersion coolant.

8. The system of claim 1, further comprising:
a container that encloses the heat generating device, prevents direct contact of the heat generating device with the two-phase liquid-immersion coolant, and is immersed in the two-phase liquid-immersion coolant.

9. A method of two-phase liquid immersion cooling a heat generating device, comprising:
positioning the heat generating device inside a cooling tank, and immersing the heat generating device within a two-phase liquid immersion coolant;
positioning a single-phase liquid coolant above the two-phase liquid coolant, which is immiscible with the two-phase liquid coolant and has a density lower than the two-phase liquid coolant; and
removing heat from the single phase liquid immersion coolant by a heat exchanger,
wherein the two-phase liquid immersion coolant is vaporized by the heat generating device, and the vaporized two-phase liquid immersion coolant is condensed by the single-phase liquid immersion coolant.

10. The method of claim 9, wherein the single-phase liquid immersion coolant is positioned above the heat generating device which is immersed in the two-phase liquid immersion coolant.

11. The method of claim 9, wherein the cooling tank is not hermetically sealed.

12. The method of claim 9, wherein an upper portion of the single-phase liquid immersion coolant in the cooling tank is at least partially open to atmosphere.

13. The method of claim 9, further comprising:
flowing the single-phase liquid immersion coolant into the heat exchanger, and
flowing single-phase liquid immersion coolant cooled below the boiling point of the two-phase liquid immersion coolant from the heat exchanger into the cooling tank.

14. The method of claim 9, wherein the single-phase liquid immersion coolant prevents the two-phase liquid immersion coolant from contacting air, and the vaporized two-phase liquid immersion coolant is cooled below its boiling point by the single-phase liquid immersion coolant.
